(19) United States
(12) Patent Application Publication
(10) Pub. No.: US 2026/0218372 A1
(43) Pub. Date: Jul. 30, 2026

(54) SEMICONDUCTOR PROCESS CHAMBER AND SEMICONDUCTOR PROCESS EQUIPMENT

(71) Applicant: BEIJING NAURA MICROELECTRONICS EQUIPMENT CO., LTD., Beijing (CN)

(72) Inventors: Guangjie KANG, Beijing (CN); Kui XU, Beijing (CN); Jianheng LUO, Beijing (CN)

(21) Appl. No.: 19/578,545

(22) Filed: Mar. 25, 2026

Related U.S. Application Data
(63) Continuation of application No. PCT/CN2024/119594, filed on Sep. 19, 2024.

(30) Foreign Application Priority Data
Sep. 28, 2023 (CN) 202311278499.8

(51) Int. Cl. C23C 14/35

(52) U.S. Cl. CPC C23C 14/35

(57) ABSTRACT

A semiconductor process chamber includes a chamber body, a carrier, a magnetron assembly, a bias magnetic field assembly, and a magnetic shielding member. The bias magnetic field assembly is located inside the chamber body and surrounds the carrier. The magnetic shielding member is located above the bias magnetic field assembly and is configured to guide the bias magnetic field above the bias magnetic field assembly, thereby reducing the magnetic field coupling of the bias magnetic field assembly and the magnetron assembly.

### CROSS-REFERENCE TO RELATED APPLICATION

This application is a continuation of International Application No. PCT/CN2024/119594, filed on Sep. 19, 2024, which claims priority to Chinese Application No. 202311278499.8, filed on Sep. 28, 2023, the entire contents of both of which are incorporated herein by reference.

### TECHNICAL FIELD

The present disclosure generally relates to the field of semiconductor technology and, more particularly, to a semiconductor process chamber and semiconductor process equipment.

### BACKGROUND

With the development of semiconductor technology, the size of processors in integrated circuit manufacturing processes has been significantly reduced. However, core components such as integrated inductors and noise suppressors still face many difficulties in the process of integration and high-frequency operation. Therefore, soft magnetic thin film materials with high magnetization intensity, high permeability, and high resonance frequency are receiving increasing attention.

This magnetic thin film is usually fabricated using a magnetron sputtering deposition process. For example, in a magnetron sputtering chamber, a bias magnetic field-induced deposition method is adopted to create a magnetic anisotropy field in-plane within the deposited soft magnetic thin film. In the sputtering process, there are two types of coupling superposition of the biased magnetic field and the magnetron magnetic field: when the horizontal components of the two magnetic fields are in the same direction, the magnetic field strength is enhanced after superposition, resulting in a higher plasma density, and more plasma will bombard the target, increasing the material sputtering rate in that area; when the horizontal components of the two magnetic fields are opposite, the magnetic field strength is weakened after superposition, resulting in a lower plasma density, and less plasma will bombard the target, reducing the material sputtering rate in that area.

Due to the two different magnetic field coupling superposition on different areas of the target surface, the rotation of the magnetron during the sputtering process causes continuous switching between the two different magnetic field coupling superposition, resulting in continuous changes in the plasma density on the target surface, thus leading to abnormal fluctuations in the voltage applied to the target during the process. Furthermore, differences in the sputtering rates across the target surface during the sputtering process can lead to uneven depressions with varying corrosion depths on the target surface. This not only affects the lifespan of the target and increases production costs, but also results in poor uniformity of the magnetic thin film deposited on the wafer surface.

### SUMMARY

The present disclosure provides a semiconductor process chamber and semiconductor process equipment to solve the technical problems of differences in the sputtering rates across the target surface and poor uniformity of the deposited magnetic thin film during the sputtering process.

The semiconductor process chamber provided in the present disclosure includes a chamber body, a carrier configured to carry a wafer, a magnetron assembly disposed above the carrier, a bias magnetic field assembly disposed within the chamber body and surrounding the carrier, and a magnetic shielding member disposed above the bias magnetic field assembly, configured to guide the magnetic field of the bias magnetic field assembly to reduce magnetic field coupling of the bias magnetic field assembly and the magnetron assembly.

The semiconductor process equipment provided in the present disclosure includes a semiconductor process chamber. The semiconductor process chamber includes a chamber body, a carrier configured to carry a wafer, a magnetron assembly disposed above the carrier, a bias magnetic field assembly disposed within the chamber body and surrounding the carrier, and a magnetic shielding member disposed above the bias magnetic field assembly, configured to guide the magnetic field of the bias magnetic field assembly to reduce magnetic field coupling of the bias magnetic field assembly and the magnetron assembly.

### BRIEF DESCRIPTION OF THE DRAWINGS

In order to more clearly illustrate the technical solutions in the embodiments of the present disclosure or the existing technology, the drawings for the description of the embodiments or the existing technology will be briefly introduced below. Obviously, the drawings in the following description are merely embodiments of the present disclosure, and for those skilled in the art, other drawings can be obtained based on the provided drawings without creative effort.

FIGS. 1a-1b schematically show the coupling superposition of the bias magnetic field and the magnetron magnetic field in related technologies;

FIG. 1c schematically shows the voltage for depositing magnetic thin film in FIGS. 1a-1b;

FIG. 1d schematically shows the corrosion depth on the surface of the target in FIGS. 1a-1b;

FIG. 1e schematically shows the thickness of the magnetic thin film deposited on the wafer surface in FIGS. 1a-1b;

FIG. 2a schematically shows a cross-sectional view of one structural form of a semiconductor process chamber and semiconductor process equipment in the present disclosure;

FIG. 2b schematically shows an enlarged view of part F in FIG. 2a;

FIG. 3a schematically shows a cross-sectional view of another structural form of a semiconductor process chamber and semiconductor process equipment in the present disclosure;

FIG. 3 b schematically shows an enlarged view of part G in FIG. 3a;

FIG. 4a schematically shows a cross-sectional view of another structural form of a semiconductor process chamber and semiconductor process equipment in the present disclosure;

FIG. 4 b schematically shows an enlarged view of part H in FIG. 4a;

FIGS. 5a-5b schematically show the coupling superposition of the bias magnetic field and the magnetron assembly magnetic field in the present disclosure;

FIG. 6 schematically shows the voltage for depositing a magnetic thin film in the present disclosure;

FIG. 7 schematically shows the corrosion depth on the surface of the target in the present disclosure;

FIG. 8 schematically shows the thickness of the magnetic thin film deposited on the wafer surface in the present disclosure;

FIG. 9 schematically shows a distribution structure of the bias magnetic field assembly in a semiconductor process chamber consistent with the present disclosure;

FIG. 10 schematically shows a partial distribution structure of a bias magnetic field assembly in a semiconductor process chamber consistent with the present disclosure;

FIG. 11 schematically shows a magnetic field distribution when the chamber is not provided with a magnetic shielding member and the distribution structure of the bias magnetic field assembly is as shown in FIG. 10;

FIG. 12 schematically shows a magnetic field distribution when the chamber is provided with a magnetic shielding member and the distribution structure of the bias magnetic field assembly is as shown in FIG. 10;

FIG. 13a is a cross-sectional schematic diagram of another structural form of semiconductor process chamber and semiconductor process equipment consistent with the present disclosure;

FIG. 13b is an enlarged schematic diagram of part J in FIG. 13a.

### REFERENCE NUMERALS

100—Chamber body; 101—Installation position mark; 110—Accommodation space;
200—Carrier;
310—Bias magnetic field assembly; 320—Fixation assembly; 321—Upper fixation plate; 322—Lower fixation plate; 330—First mounting part; 331—Scale mark; 340—Second mounting part;
400—Magnetic shielding member; 401—Recess; 402—Gap;
500—Liner assembly; 510—Groove;
600—Shielding ring;
610—Annular body; 620—First protrusion; 630—Second protrusion; 640—Third protrusion;
700—Heat insulation ring;
800—Magnetron assembly; 810—Target; 820—Motor; 830—Deionized water;
900—Wafer; 910—Magnetic thin film.

### Detailed Description of the Embodiments

The details of technical solutions of the present disclosure will be described below with reference to the accompanying drawings. Obviously, the described embodiments are only some embodiments of the present disclosure, not all of them. Based on the described embodiments, all other embodiments obtained by those skilled in the art without making creative efforts are within the scope of the present disclosure.

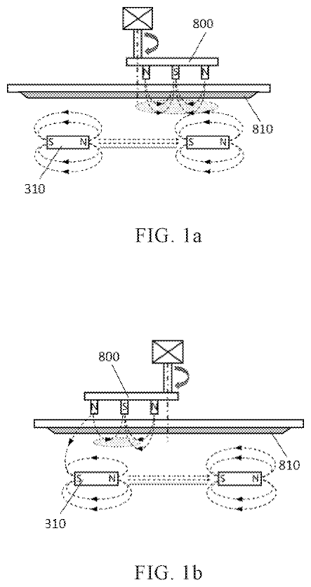

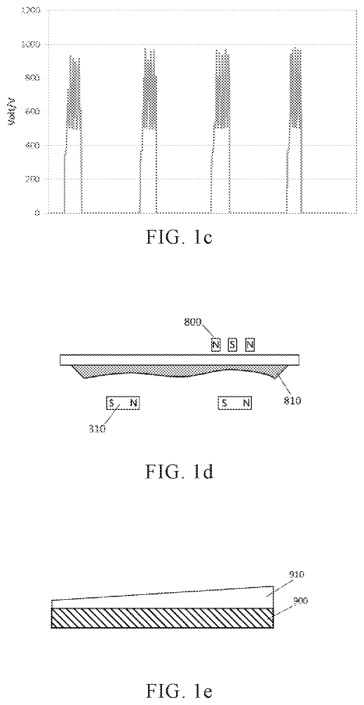

As shown in FIGS. 1a-1e, in the related sputtering process technology, a bias magnetic field is set. The bias magnetic field is a horizontal magnetic field parallel to the surface of the carrier (i.e., the carrying surface), so that when sputtering deposition of magnetic materials, the magnetic field of the magnetic material is aligned in the horizontal direction, forming an easy magnetization field in this direction, and a hard magnetization field in the direction perpendicular to this direction in the plane, thus forming an in-plane anisotropic magnetic field, resulting in an in-plane anisotropic magnetic thin film. In the sputtering process, as shown in FIGS. 1a-1b, there are two magnetic fields: one formed by the magnetron assembly 800 on the surface of the target 810, and another formed by the bias magnetic field assembly 310 on the surface of the target 810. Only the magnetic field parallel to the surface of the target 810 in the chamber will confine the electrons in the plasma. Both the magnetron assembly 800 and the bias magnetic field assembly 310 have horizontal magnetic field components on the surface of the target 810. As shown in FIG. 1a, when the horizontal components of the two magnetic fields are in the same direction, the magnetic field strength is enhanced after the superposition of the two magnetic fields, resulting in a higher plasma density. This causes more ions (e.g., Ar⁺) in the plasma to bombard the target, increasing the sputtering rate in this region. Similarly, as shown in FIG. 1b, when the horizontal components of the two magnetic fields are in opposite directions, the magnetic field strength is weakened after the superposition of the two magnetic fields, resulting in a lower plasma density. This causes fewer ions (e.g., Ar⁺) in the plasma to bombard the target, reducing the sputtering rate in this region.

Due to the different coupling superposition of the two magnetic fields on the target surface, the rotation of the magnetron during the process causes the coupling effect of the two magnetic fields in the chamber to continuously switch, resulting in continuous changes in the plasma density on the target surface. This leads to abnormal fluctuations in the voltage applied to the target during the process, as shown in FIG. 1c. When the voltage fluctuates abnormally, the machine triggers an alarm, preventing the process from being completed. Furthermore, the differences in the sputtering rates across the target surface cause depressions with varying depths, as shown in FIG. 1d, affecting the lifespan of the target 810 and increasing production costs. In addition, on the surface of the wafer 900, the magnetic film layer 910 deposited below the region where the magnetic field superposition is enhanced is thicker, while the magnetic film layer 910 deposited below the region where the magnetic field superposition is weakened is thinner, resulting in poor uniformity of the deposited magnetic thin film, as shown in FIG. 1e.

In the present disclosure, to address the technical problems of abnormal voltage fluctuations caused by the superposition of magnetic fields, uneven target corrosion depth, and poor uniformity of the deposited magnetic thin film, a magnetic shielding member 400 is provided above the bias magnetic field assembly 310. This magnetic shielding member 400 can guide the bias magnetic field above the bias magnetic field assembly 310, thereby weakening or even avoiding the adverse effects of the coupling superposition of the bias magnetic field and the magnetron magnetic field, as described in detail below.

The present disclosure will be further described in detail below through specific embodiments and in conjunction with the accompanying drawings.

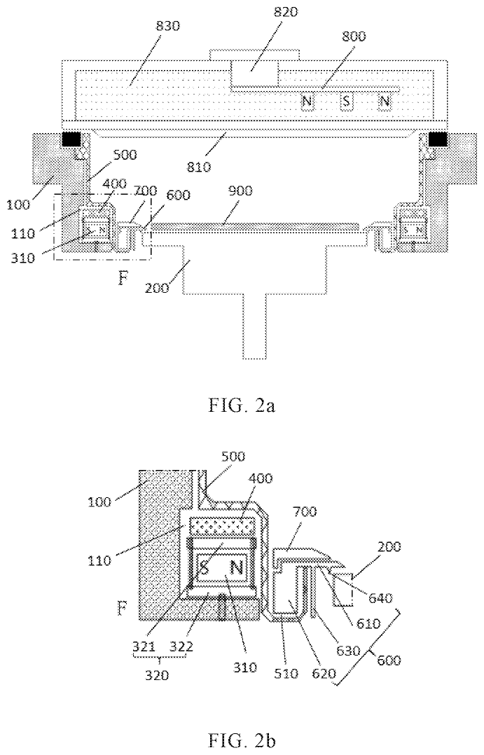

The present disclosure provides a semiconductor process chamber, taking the magnetron sputtering process as an example, as shown in FIGS. 2a-2b, 3a-3b, and 4a-4b. The semiconductor process chamber includes: a chamber body 100, a carrier 200, a magnetron assembly 800, a bias magnetic field assembly 310, and a magnetic shielding member 400. The carrier 200 is configured to carry the wafer 900; the bias magnetic field assembly 310 is fixed inside the chamber body 100 and surrounds the carrier 200; the magnetic shielding member 400 is located above the bias magnetic field assembly 310 and is configured to guide the bias magnetic field of the bias magnetic field assembly 310 to reduce the magnetic field coupling of the bias magnetic field assembly 310 and the magnetron assembly 800.

In the present disclosure, during the process, the bias magnetic field of the bias magnetic field assembly 310 forms a horizontal magnetic field on the surface of the wafer 900, so that the magnetic material sputtered onto the surface of the wafer 900 has in-plane anisotropic field, thereby obtaining an in-plane anisotropic magnetic thin film 910. The magnetic shielding member 400 is located above the bias magnetic field assembly 310, and the magnetic shielding member 400 can guide the bias magnetic field above the bias magnetic field assembly 310, thereby reducing the magnetic field range above the bias magnetic field assembly 310. This means that the magnetic field above the bias magnetic field assembly 310 is guided through the magnetic shielding member 400 as much as possible, thus increasing the distance between the bias magnetic field above the bias magnetic field assembly 310 and the magnetic field of the magnetron assembly 800 in the semiconductor process chamber. In this way, during the sputtering process, the magnetic field coupling of the bias magnetic field assembly 310 and the magnetron assembly 800 can be weakened or even avoided, thereby ensuring the uniformity of the plasma concentration and sputtering rate on the surface of the target 810, reducing or even avoiding abnormal fluctuations in the voltage applied to the target 810, ensuring the uniformity of the corrosion depth on the surface of the target 810, that is, reducing or avoiding the formation of depressions with varying corrosion depths on the surface of the target 810, ensuring the service life of the target 810, reducing production costs, and ensuring the uniformity of the magnetic thin film 910 deposited on the surface of the wafer 900.

Specifically, the carrier 200 includes a base for carrying the wafer 900. The bias magnetic field assembly 310 may include a magnet fixed within the chamber body 100 and located on the outer periphery of the carrier 200, i.e., surrounding the outer wall of the base; the magnetic shielding member 400 is located within the bias magnetic field range above the bias magnetic field assembly 310 and close to the bias magnetic field assembly 310. This can minimize the magnetic field range of the bias magnetic field above the bias magnetic field assembly 310, thereby further weakening the magnetic field coupling of the bias magnetic field assembly 310 and the magnetron assembly 800.

Consistent with the present disclosure, the magnetic shielding member 400 is mainly made of magnetic material. Any magnetic material that has no impact on the chamber and process results can be used, such as 410 stainless steel; the shape of the magnetic shielding member 400 can be a ring or an arc structure. The present disclosure does not specify any limitations on the thickness or radial width of the magnetic shielding member 400, as long as the magnetic shielding member 400 provides effective magnetic shielding and does not interfere with other components within the chamber. For example, in the present disclosure, the magnetic shielding member 400 has a thickness of 8 mm and a radial width of 28 mm. Further, there is a magnetic attraction between the magnetic shielding member 400 and the bias magnetic field assembly 310. This magnetic attraction can fix the magnetic shielding member 400 and the bias magnetic field assembly 310 together, so there is no need to set up a separate fixation structure; of course, setting a fixation structure between the magnetic shielding member 400 and the bias magnetic field assembly 310 to make their relative position more stable is also within the scope of the present disclosure.

Consistent with the present disclosure, as shown in FIGS. 2a-2b, 3a-3b, and 4a-4b, the downward projection area of the magnetic shielding member 400 can cover the bias magnetic field assembly 310. This allows for guiding the magnetic field over a larger area above the bias magnetic field assembly 310 as much as possible. Specifically, for example, the magnetic shielding member 400 can be a ring-shaped flat plate structure.

Consistent with the present disclosure, as shown in FIGS. 2a-2b, 3a-3b, and 4a-4b, a fixation assembly 320 can also be provided. The fixation assembly 320 is fixed within the space enclosed by the inner wall of the chamber body 100, and the bias magnetic field assembly 310 is fixed to the fixation assembly 320. For example, the fixation assembly 320 includes a mounting part for fixing and installing the bias magnetic field assembly 310 to ensure the installation stability of the bias magnetic field assembly 310.

Consistent with the present disclosure, as shown in FIGS. 2a-2b, the fixation assembly 320 includes an upper fixation plate 321 and a lower fixation plate 322 that are fixed together. The lower fixation plate 322 is fixed within the space enclosed by the inner wall of the chamber body 100. Specifically, the upper fixation plate 321 and the lower fixation plate 322 are fixed together by fasteners (bolts or screws). The space between the upper fixation plate 321 and the lower fixation plate 322 forms a mounting part for fixing and installing the bias magnetic field assembly 310, i.e., the bias magnetic field assembly 310 is fixed between the upper fixation plate 321 and the lower fixation plate 322, and the magnetic shielding member 400 is located above the upper fixation plate 321. The material of the upper fixation plate and lower fixation plate is not limited in the present disclosure, as long as the upper fixation plate and lower fixation plate do not adversely affect the semiconductor process chamber and the process results. The present disclosure takes stainless steel as an example.

Regarding the arrangement of the fixation assembly 320 and the magnetic shielding member 400, in addition to the arrangement described above, other arrangements can also be adopted and are described in detail below.

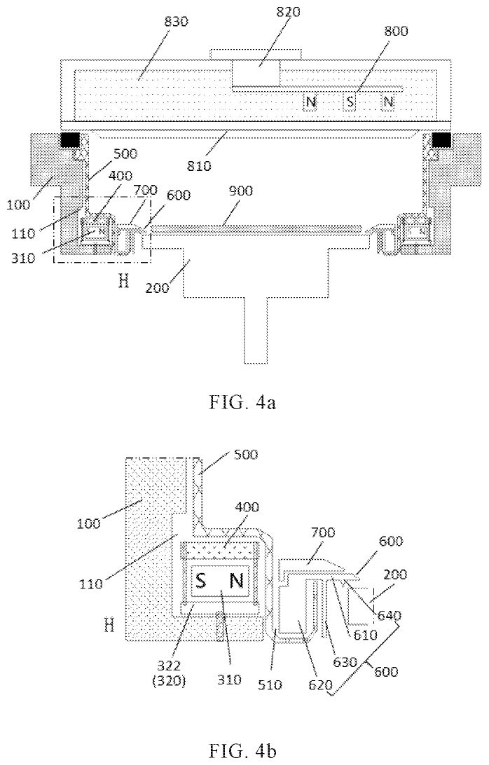

For example, the fixation assembly 320 mainly includes a lower fixation plate 322, as shown in FIGS. 4a-4b. The lower fixation plate 322 is fixed within the space enclosed by the inner wall of the chamber body 100. The bias magnetic field assembly 310 is fixed on the upper surface of the lower fixation plate 322, and the magnetic shielding member 400 is located above the bias magnetic field assembly 310. In this case, the mounting part can be arranged on the upper surface of the lower fixation plate 322, and the bias magnetic field assembly 310 is fixed between the magnetic shielding member 400 and the lower fixation plate 322;

As another example, the fixation assembly 320 mainly includes an upper fixation plate 321 (this example is not shown in the figure). The upper fixation plate 321 is fixed within the space enclosed by the inner wall of the chamber body 100. The bias magnetic field assembly 310 is located between the upper fixation plate 321 and the chamber body 100, and the magnetic shielding member 400 is located above the upper fixation plate 321; in this case, the mounting part can be arranged on the lower surface of the upper fixation plate 321, and the bias magnetic field assembly 310 is fixed between the upper fixation plate 321 and the inner bottom wall of the chamber body 100;

Therefore, the arrangement of the fixation assembly 320 and the magnetic shielding member 400 is not limited in the present disclosure. The arrangement is acceptable as long as the magnetic shielding member 400 is located above the bias magnetic field assembly 310, capable of shielding the bias magnetic field assembly 310 from top to bottom, and the magnetic shielding member 400 is within the bias magnetic field range above the bias magnetic field assembly 310. The effect is better if the magnetic shielding member 400 is positioned as close as possible to the bias magnetic field assembly 310.

Consistent with the present disclosure, as shown in FIGS. 2a-2b, 3a-3b, and 4a-4b, the semiconductor process chamber can also be provided with a liner assembly 500. The liner assembly 500 covers the inner wall of the chamber body 100, and there is an accommodation space 110 between the outer wall of the liner assembly 500 and the inner wall of the chamber body 100. The relative positions of the bias magnetic field assembly 310 and the magnetic shielding member 400 with respect to the accommodation space 110 are as follows:

For example, the bias magnetic field assembly 310 can be fixed within the accommodation space 110. This arrangement allows the liner assembly 500 to prevent magnetic material sputtered from the target 810 from being deposited on the inner wall of the chamber body 100 and above the bias magnetic field assembly 310, thus avoiding affecting the performance of the bias magnetic field assembly 310. When the bias magnetic field assembly 310 is fixed within the accommodation space 110, the magnetic shielding member 400 can also be arranged within the accommodation space 110, further, the fixation assembly 320 can be fixed within the accommodation space 110. For example, when the fixation assembly 320 includes the lower fixation plate 322 but not the upper fixation plate 321, the side wall of the liner assembly 500, the magnetic shielding member 400, the bias magnetic field assembly 310, the lower fixation plate 322, and the side wall of the chamber body 100 are arranged sequentially from top to bottom; when the fixation assembly 320 includes the upper fixation plate 321 but not the lower fixation plate 322, the side wall of the liner assembly 500, the magnetic shielding member 400, the upper fixation plate 321, the bias magnetic field assembly 310, and the side wall of the chamber body 100 are arranged sequentially from top to bottom; when the fixation assembly 320 includes both the upper fixation plate 321 and the lower fixation plate 322, the side wall of the liner assembly 500, the magnetic shielding member 400, the upper fixation plate 321, the bias magnetic field assembly 310, the lower fixation plate 322, and the side wall of the chamber body 100 are arranged sequentially from top to bottom.

When the bias magnetic field assembly 310 is fixed within the accommodation space 110, the magnetic shielding member 400 can also be arranged in the space enclosed by the inner wall of the liner assembly 500. In this case, the magnetic shielding member 400 is located outside the accommodation space 110, and the fixation assembly 320 is fixed within the accommodation space 110. For example, when the fixation assembly 320 includes the lower fixation plate 322 but not the upper fixation plate 321, the magnetic shielding member 400, the side wall of the liner assembly 500, the bias magnetic field assembly 310, the lower fixation plate 322, and the side wall of the chamber body 100 are arranged sequentially from top to bottom; when the fixation assembly 320 includes the upper fixation plate 321 but not the lower fixation plate 322, the magnetic shielding member 400, the side wall of the liner assembly 500, the upper fixation plate 321, the bias magnetic field assembly 310, and the side wall of the chamber body 100 are arranged sequentially from top to bottom; when the fixation assembly 320 includes both the upper fixation plate 321 and the lower fixation plate 322, the magnetic shielding member 400, the side wall of the liner assembly 500, the upper fixation plate 321, the bias magnetic field assembly 310, the lower fixation plate 322, and the side wall of the chamber body 100 are arranged sequentially from top to bottom.

As another example, the bias magnetic field assembly 310 and the magnetic shielding member 400 can both be fixed in the space enclosed by the inner wall of the liner assembly 500. In this case, both the bias magnetic field assembly 310 and the magnetic shielding member 400 are located outside the accommodation space 110. In this case, the fixation assembly 320 is fixed in the space enclosed by the inner wall of the liner assembly 500, i.e., outside the accommodation space 110. For example, when the fixation assembly 320 includes the lower fixation plate 322 but not the upper fixation plate 321, the magnetic shielding member 400, the bias magnetic field assembly 310, the lower fixation plate 322, the side wall of the liner assembly 500, and the side wall of the chamber body 100 are arranged sequentially from top to bottom; when the fixation assembly 320 includes the upper fixation plate 321 but not the lower fixation plate 322, the magnetic shielding member 400, the upper fixation plate 321, the bias magnetic field assembly 310, the side wall of the liner assembly 500, and the side wall of the chamber body 100 are arranged sequentially from top to bottom; when the fixation assembly 320 includes both the upper fixation plate 321 and the lower fixation plate 322, the magnetic shielding member 400, the upper fixation plate 321, the bias magnetic field assembly 310, the lower fixation plate 322, the side wall of the liner assembly 500, and the side wall of the chamber body 100 are arranged sequentially from top to bottom.

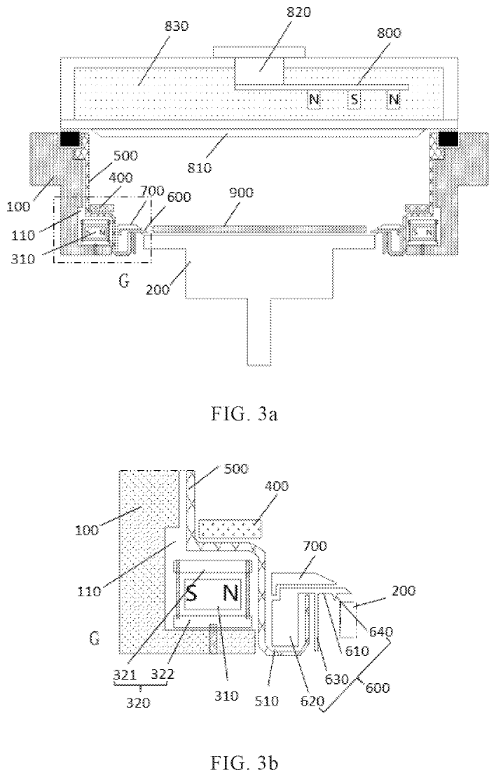

In the embodiments of the present disclosure, as shown in FIGS. 2a-2b and 4a-4b, the magnetic shielding member 400 can be arranged inside the accommodation space 110 and above the bias magnetic field assembly 310. This arrangement prevents magnetic material sputtered from the target 810 from being deposited on the magnetic shielding member 400, thus avoiding affecting the magnetic permeability of the magnetic shielding member 400. In some embodiments, as shown in FIGS. 3a-3b, the magnetic shielding member 400 can be arranged within the space enclosed by the inner wall of the liner assembly 500, that is, above the accommodation space 110 and outside the accommodation space 110, within the space enclosed by the inner wall of the liner assembly 500. With this arrangement, the magnetic shielding member 400 can still guide the magnetic field above the bias magnetic field assembly 310, at least partially mitigating the adverse effects of the coupling superposition of the magnetic fields of the magnetron assembly 800 and the bias magnetic field assembly 310. However, the magnetic material sputtered from the target 810 may fall onto the magnetic shielding member 400, which may affect the magnetic permeability of the magnetic shielding member 400.

It should be noted that the connection method between the upper fixation plate and lower fixation plate and the chamber body can be achieved using fasteners such as bolts, screws, and pins; the connection method between the upper fixation plate and lower fixation plate and the liner assembly can be achieved using fasteners such as bolts, screws, and pins; the connection method between the upper fixation plate and lower fixation plate can be achieved using fasteners such as bolts, screws, and pins. The connection methods are not limited in the present disclosure, and any method that achieves the corresponding connection relationship is within the scope of the present disclosure.

As shown in FIGS. 2a-2b, 3a-3b, and 4a-4b, the specific structure of the liner assembly 500 is not limited in the present disclosure, for example, the liner assembly 500 can be configured into a structure such that its inner wall forms a stepped space, and the radial dimension of this stepped space decreases from top to bottom. The lower end of the liner assembly 500 extends into the gap between the outer periphery of the carrier 200 and the chamber body 100 to seal this gap. With this arrangement, the accommodation space 110 can be formed by the lower surface of the step of the liner assembly 500, the outer side wall of the liner assembly 500 below this lower surface, the inner side wall of the lower end of the chamber body 100, and the inner bottom wall of the chamber body 100. When the bias magnetic field assembly 310 is placed in the accommodation space 110, and the magnetic shielding member 400 is placed in the space enclosed by the inner wall of the liner assembly 500, the magnetic shielding member 400 can be arranged on the upper surface of the step of the liner assembly 500. Furthermore, the lower end of the liner assembly 500 extends into the gap between the outer periphery of the carrier 200 and the chamber body 100 to seal this gap, preventing magnetic material sputtered from the target 810 from leaking through this gap.

Consistent with the present disclosure, as shown in FIGS. 2a-2b, 3a-3b, and 4a-4b, the semiconductor process chamber can also be provided with a shielding ring 600. The shielding ring 600 has an annular body 610, and the lower end of the annular body 610 includes a first protrusion 620 and a second protrusion 630 extending downwards at intervals. The first protrusion 620 and the second protrusion 630 are arranged sequentially inward along the radial direction (i.e., from the outer ring to the inner ring of the annular body 610). The radial dimension of the inner ring of the annular body 610 is smaller than the radial dimension of the outer edge of the upper end surface of the carrier 200, and the inner ring of the annular body 610 is located above the carrier 200. The lower end of the liner assembly 500 has an upward-facing groove 510. The first protrusion 620 is inserted into the groove 510, and the second protrusion 630 is inserted into the gap between the outer side wall of the groove 510 and the outer peripheral wall of the carrier 200. With this arrangement, the annular body 610 can seal the gap between the lower end of the liner assembly 500 and the outer peripheral wall of the carrier 200, preventing magnetic material sputtered from the target 810 from leaking through this gap. The first protrusion 620, the second protrusion 630, and the groove 510 are interlocked, which can determine the relative position between the annular body 610 and the liner assembly 500 in the radial direction. During the process, the carrier 200 can come into contact with the shielding ring 600 after being moved up. At this time, the bias magnetic field of the bias magnetic field assembly 310 will form a horizontal magnetic field on the surface of the wafer 900, so that the magnetic material sputtered onto the wafer surface has an in-plane anisotropic field, thereby obtaining an in-plane anisotropic magnetic thin film.

Specifically, the annular body 610 can adopt an annular plate-like structure, and the first protrusion 620 and the second protrusion 630 can be columnar protrusions or cylindrical shell structures. The radial thickness of the first protrusion 620 can be set to match the radial width of the groove 510, minimizing the gap between the outer edge of the annular body 610 and the inner wall of the lower end of the liner assembly 500, to reduce or even prevent magnetic material sputtered from the target 810 from falling into the groove 510; the distance between the first protrusion 620 and the second protrusion 630 can be set to match the wall thickness of the groove 510 for further radial positioning.

Consistent with the present disclosure, as shown in FIGS. 2a-2b, 3a-3b, and 4a-4b, the lower end of the annular body 610 extends downward with a third protrusion 640. The first protrusion 620, the second protrusion 630, and the third protrusion 640 are arranged sequentially inward along the radial direction (i.e., from the outer ring to the inner ring of the annular body 610). That is, compared to the second protrusion 630, the third protrusion 640 is closer to the carrier 200. The axial dimension of the third protrusion 640 is smaller than the axial dimension of the second protrusion 630, and the part of the third protrusion 640 closer to the carrier 200 has an inclined surface. The inclined surface slopes radially outward from top to bottom, and the inclined surface is configured to define the relative position of the carrier 200 and the annular body 610. The axial dimension here refers to the dimension extending downward from the lower end of the annular body 610 in the vertical direction. Based on this, the inclined surface of the third protrusion 640 closer to the carrier 200 extends and slopes radially outward from top to bottom. This arrangement not only defines the relative position between the annular body 610 and the carrier 200, but the inclined surface also serves as a guiding function.

Consistent with the present disclosure, as shown in FIGS. 2a-2b, 3a-3b, and 4a-4b, the semiconductor process chamber also includes a heat insulation ring 700 positioned above the shielding ring 600. The heat insulation ring 700 effectively insulates heat, preventing the high temperatures generated during the process from causing deformation of the shielding ring 600. Specifically, the shielding ring 600 and the heat insulation ring 700 are detachably connected, for example, by snap-fitting. For instance, one of them has a slot, and the other has a corresponding latch. As shown in FIGS. 2a-2b, 3a-3b, and 4a-4b, the outer edge of the upper surface of the shielding ring 600 has a downward-facing notch forming a slot with the inner wall of the liner assembly 500. The lower end of the outer edge of the heat insulation ring 700 extends downward to form a protruding part acting as a latch. The protruding part of the heat insulation ring 700 is snapped into the notch of the shielding ring 600, thus preventing radial displacement between the shielding ring 600 and the heat insulation ring 700.

Consistent with the present disclosure, the bias magnetic field assembly 310 includes magnets. The magnets can be configured as columnar structures, with their axes along the radial direction of the carrier 200, i.e., the columnar magnets are placed horizontally. There are multiple magnets, arranged sequentially along the circumferential direction of the chamber body 100. There can be various specific arrangements of the magnets. For example, multiple magnets are arranged in a set, with each group of magnets arranged sequentially along the circumferential direction of the chamber body 100, forming an annular sector region. Multiple sets of magnets are provided, and the multiple sets of magnets are uniformly or symmetrically arranged along the circumferential direction of the chamber body 100 or the carrier 200. For example, two sets of magnets are provided, and they are axially symmetrical or centrally symmetrical with respect to the axis of the chamber body 100.

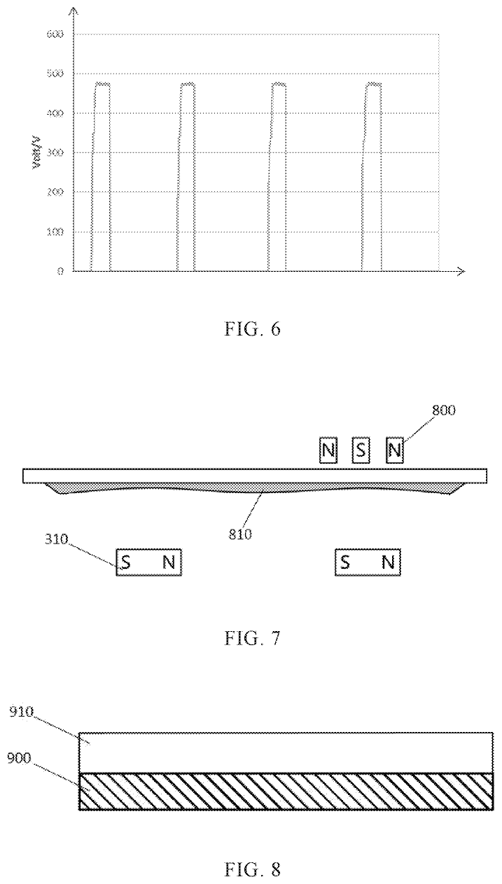

As described above, consistent with the present disclosure, a magnetic shielding member 400 is provided in the process chamber for depositing magnetic thin films, as shown in FIGS. 2a-2b, 3a-3b, and 4a-4b. Since the magnetic shielding member 400 is capable of magnetic guiding, placing the magnetic shielding member 400 in the bias magnetic field range above the bias magnetic field assembly 310 allows the magnetic field lines to pass through the magnetic shielding member 400 from the N pole back to the S pole, reducing the magnetic field range above the bias magnetic field assembly 310. In this way, the magnetic field on the surface of the wafer 900 in the horizontal direction will not be affected, and the magnetic field coupling superposition of the bias magnetic field above the bias magnetic field assembly 310 and the magnetic field of the magnetron assembly 800 on the surface of the target 810 can also be weakened, reducing or even avoiding the influence of the magnetron rotation in the magnetron assembly 800 on the plasma density on the surface of the target 810, and reducing or even avoiding abnormal fluctuations in the voltage applied to the target during the process. As shown in FIG. 6, the voltage applied to the target tends to be stable. Furthermore, the corrosion depth on the surface of the target 810 is essentially uniform, as shown in FIG. 7. This can improve the utilization rate of the target and reduce costs, and also improve the problem of poor uniformity of the magnetic thin film 910 deposited on the surface of the wafer 900, as shown in FIG. 8, resulting in a magnetic thin film 910 with better uniformity on the surface of the wafer 900.

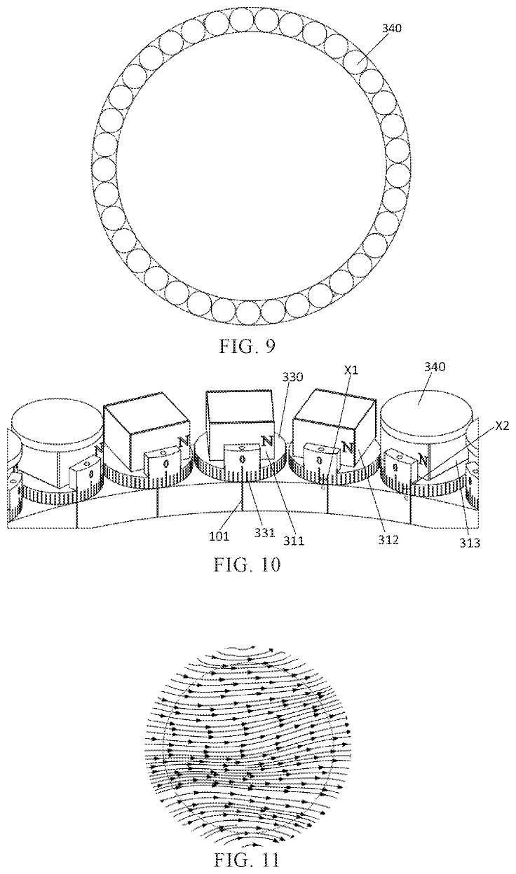

FIG. 9 schematically shows the distribution structure of a bias magnetic field assembly in a semiconductor process chamber consistent with the present disclosure. The bias magnetic field assembly is disposed within the chamber body and surrounds the carrier. The present disclosure does not limit the number of bias magnetic field assemblies; in practical applications, the number can be selected according to actual needs. For example, multiple bias magnetic field assemblies can be evenly arranged around the carrier. In FIG. 9, a mounting part (e.g., the second mounting part 340 hereinafter) is provided above the bias magnetic field assembly, and is shown as a circular pattern in FIG. 9. Since the mounting part above the bias magnetic field assembly covers the bias magnetic field assembly, the bias magnetic field assembly is not marked in FIG. 9.

FIG. 10 schematically shows a partial distribution structure of a bias magnetic field assembly in a semiconductor process chamber consistent with the present disclosure. As shown in FIG. 10, to facilitate the demonstration of the structure of the bias magnetic field assembly, the second mounting part above part of the bias magnetic field assembly is removed. As shown in FIG. 10, the internal magnetic field direction of the bias magnetic field assembly 310 is parallel to the carrying surface of the carrier. The internal magnetic field direction of the bias magnetic field assembly 310 refers to the direction from the S pole to the N pole inside the magnet. FIG. 10 only shows the N pole of the bias magnetic field assembly 310; the S pole is the end of the bias magnetic field assembly 310 opposite to the N pole. Consistent with the present disclosure, the bias magnetic field assembly 310 is exemplarily configured as a cuboid, thereby preventing the bias magnetic field assembly from rolling.

Consistent with the present disclosure, the bias magnetic field assemblies surrounding the carrier can be distributed in any of the following ways:

Along the circumference of the carrier in a clockwise direction, the internal magnetic field direction of the following bias magnetic field assembly is rotated clockwise by a predetermined angle relative to the internal magnetic field direction of the preceding bias magnetic field assembly;

In some embodiments, along the circumference of the carrier in a clockwise direction, the internal magnetic field direction of the following bias magnetic field assembly is rotated counterclockwise by a predetermined angle relative to the internal magnetic field direction of the preceding bias magnetic field assembly;

In some embodiments, along the circumference of the carrier in a counterclockwise direction, the internal magnetic field direction of the following bias magnetic field assembly is rotated clockwise by a predetermined angle relative to the internal magnetic field direction of the preceding bias magnetic field assembly;

In some embodiments, along the circumference of the carrier in a counterclockwise direction, the internal magnetic field direction of the following bias magnetic field assembly is rotated counterclockwise by a predetermined angle relative to the internal magnetic field direction of the preceding bias magnetic field assembly.

FIG. 10 illustrates an example where, in any two adjacent bias magnetic field assemblies arranged clockwise around the circumference of the carrier, the internal magnetic field direction of the following bias magnetic field assembly is rotated clockwise by a predetermined angle relative to the internal magnetic field direction of the preceding bias magnetic field assembly.

For ease of description, three bias magnetic field assemblies are labeled in FIG. 10, that is, bias magnetic field assembly 311, bias magnetic field assembly 312, and bias magnetic field assembly 313. Bias magnetic field assembly 311, bias magnetic field assembly 312, and bias magnetic field assembly 313 are arranged sequentially clockwise around the circumference of the carrier. Bias magnetic field assembly 311 and bias magnetic field assembly 312 are two adjacent bias magnetic field assemblies, with the internal magnetic field direction of bias magnetic field assembly 312 rotated clockwise by a predetermined angle θ1 relative to the internal magnetic field direction of bias magnetic field assembly 311. Similarly, bias magnetic field assembly 312 and bias magnetic field assembly 313 are two adjacent bias magnetic field assemblies, with the internal magnetic field direction of bias magnetic field assembly 313 rotated clockwise by a predetermined angle θ2 relative to the internal magnetic field direction of bias magnetic field assembly 312.

FIG. 10 illustrates the example where, in a clockwise direction around the circumference of the carrier, the internal magnetic field direction of the following bias magnetic field assembly is rotated clockwise by a predetermined angle relative to the internal magnetic field direction of the preceding bias magnetic field assembly. In some embodiments, in a clockwise direction around the circumference of the carrier, the internal magnetic field direction of the following bias magnetic field assembly may be rotated counterclockwise by a predetermined angle relative to the internal magnetic field direction of the preceding bias magnetic field assembly; or, in a counterclockwise direction around the circumference of the carrier, the internal magnetic field direction of the following bias magnetic field assembly may be rotated clockwise by a predetermined angle relative to the internal magnetic field direction of the preceding bias magnetic field assembly; or, in a counterclockwise direction around the circumference of the carrier, the internal magnetic field direction of the following bias magnetic field assembly may be rotated counterclockwise by a predetermined angle relative to the internal magnetic field direction of the preceding bias magnetic field assembly.

Consistent with the present disclosure, the angle between the internal magnetic field directions of any two adjacent bias magnetic field assemblies can be the same or different. For example, three bias magnetic field assemblies arranged sequentially along the circumference of the carrier are bias magnetic field assembly A1, bias magnetic field assembly A2, and bias magnetic field assembly A3. The angle between the internal magnetic field directions of magnetic field component A1 and bias magnetic field assembly A2 is α1, and the angle between the internal magnetic field directions of bias magnetic field assembly A2 and bias magnetic field assembly A3 is α2. α1 and α2 can be the same or different.

As shown in FIG. 10, the angle between the internal magnetic field directions of any adjacent bias magnetic field assemblies is set to be the same. As shown in FIG. 10, the internal magnetic field direction of bias magnetic field assembly 312 is rotated clockwise by a predetermined angle θ1 relative to the internal magnetic field direction of bias magnetic field assembly 311, and the internal magnetic field direction of bias magnetic field assembly 313 is rotated clockwise by a predetermined angle θ2 relative to the internal magnetic field direction of bias magnetic field assembly 312. The angle between the internal magnetic field directions of bias magnetic field assembly 312 and bias magnetic field assembly 311 is θ1, and the angle between the internal magnetic field directions of bias magnetic field assembly 313 and bias magnetic field assembly 312 is θ2, where θ2=θ1. Along the circumference of the carrier in a clockwise direction, in any two adjacent bias magnetic field assemblies, the internal magnetic field direction of the following bias magnetic field assembly is rotated clockwise by the same predetermined angle relative to the internal magnetic field direction of the preceding bias magnetic field assembly. Therefore, the angle between the internal magnetic field directions of any adjacent bias magnetic field assemblies is the same.

Consistent with the present disclosure, the angle between the internal magnetic field directions of any adjacent bias magnetic field assemblies ranges from 5°to 20°.

Consistent with the present disclosure, as shown in FIG. 10, a first mounting part 330 is further included, and the bias magnetic field assembly 310 is fixedly mounted at the chamber body 100 through the first mounting part 330. A scale mark 331 is provided at the first mounting part 330. An installation position mark 101 is provided at the chamber body 100. In any two adjacent bias magnetic field assemblies, the scale mark aligned with the installation position mark on the first mounting part of the preceding bias magnetic field assembly is the first scale mark, and the scale mark aligned with the installation position mark on the first mounting part of the following bias magnetic field assembly is the second scale mark. The absolute value of the difference between the first scale mark and the second scale mark is a predetermined angle by which the internal magnetic field direction of the following bias magnetic field assembly rotates relative to the internal magnetic field direction of the preceding bias magnetic field assembly.

Taking the adjacent bias magnetic field assemblies 312 and 313 in FIG. 10 as examples, the scale mark aligned with the installation position mark on the first mounting part of the bias magnetic field assembly 312 is designated as the first scale mark X1, and the scale mark aligned with the installation position mark on the first mounting part of the bias magnetic field assembly 313 is designated as the second scale mark X2. The absolute value of the difference between the first scale mark X1 and the second scale mark X2 is a predetermined angle by which the internal magnetic field direction of the bias magnetic field assembly 313 rotates relative to the internal magnetic field direction of the bias magnetic field assembly 312.

The present disclosure provides a scale mark 331 on the first mounting part 330 and an installation position mark 101 on the chamber body 100 to facilitate the precise placement of the bias magnetic field assembly 310 on the chamber body according to the deflection angle of the internal magnetic field direction.

Consistent with the present disclosure, as shown in FIG. 10, a second mounting part 340 is also included. The bias magnetic field assembly 310 is located between the second mounting part 340 and the first mounting part 330. The second mounting part 340 is fixedly connected to the first mounting part 330 by fasteners.

In some embodiments, the bias magnetic field assembly 310 and the second mounting part 340 can be arranged in a one-to-one correspondence, that is, each bias magnetic field assembly 310 is provided with a corresponding second mounting part 340.

In some embodiments, the second mounting part can be arranged in a ring shape, and all bias magnetic field assemblies share the second mounting part. Consistent with the present disclosure, each bias magnetic field assembly is mounted and fixed using a ring-shaped second mounting part.

Consistent with the present disclosure, the second mounting part can be reused as a magnetic shielding member. For example, the second mounting part is made of a magnetically conductive material, the bias magnetic field of the bias magnetic field assembly 310 can be guided by the second mounting part, thereby reducing the magnetic field coupling between the bias magnetic field assembly 310 and the magnetron assembly 800, eliminating the need for an additional magnetic shielding member.

Consistent with the present disclosure, the bias magnetic field assemblies are arranged in a Halbach array along the circumference of the carrier in a clockwise or counterclockwise direction, thereby achieving a relatively uniform anisotropic magnetic field distribution at the carrying surface of the carrier.

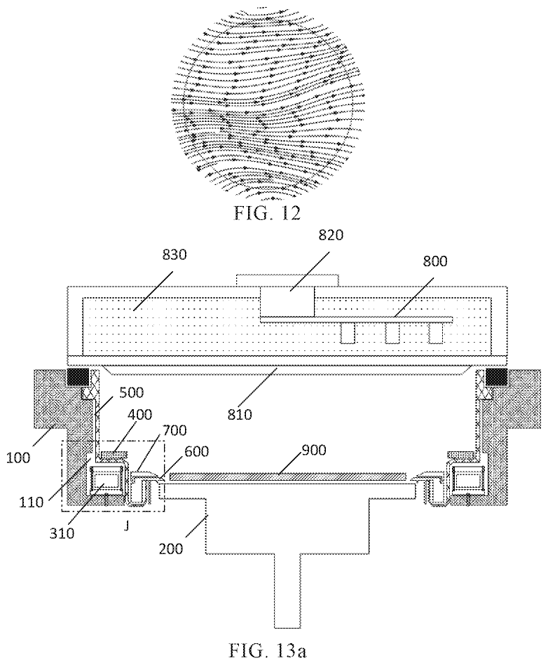

FIG. 11 schematically shows a magnetic field distribution diagram when the chamber is not provided with a magnetic shielding member and the bias magnetic field assembly distribution structure is as shown in FIG. 10. FIG. 12 schematically shows the magnetic field distribution when the chamber is provided with a magnetic shielding member and the bias magnetic field assembly is distributed as shown in FIG. 10. The solid circular lines in FIGS. 11 and 12 represent the wafer edge positions. As shown in FIG. 11, a relatively uniform anisotropic magnetic field distribution is formed at the carrying surface of the carrier. As shown in FIG. 12, with the magnetic shielding member inside the chamber, the impact on the magnetic field uniformity at the carrying surface of the carrier is small; the magnetic field at the carrying surface of the carrier still exhibits a relatively uniform anisotropic magnetic field distribution.

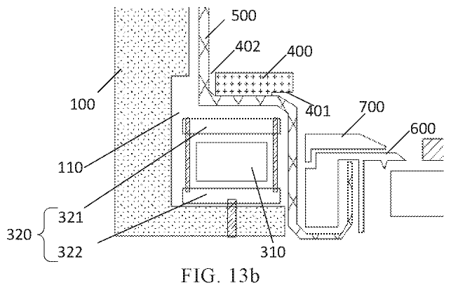

FIG. 13a is a cross-sectional schematic diagram of a semiconductor process chamber and semiconductor process equipment with another structural form consistent with the present disclosure; FIG. 13b is an enlarged schematic diagram of part J in FIG. 13a. As shown in FIGS. 13a and 13b, consistent with the present disclosure, the semiconductor process chamber further includes a liner assembly 500 covering the inner wall of the chamber body 100; the magnetic shielding member 400 is located within the space enclosed by the inner wall of the liner assembly 500.

A recess 401 is provided at the lower surface of the end of the magnetic shielding member 400 adjacent to the carrier 200, and/or, in a direction parallel to the carrying surface of the carrier 200, a gap 402 exists between the end of the magnetic shielding member 400 away from the carrier 200 and the liner assembly.

When the magnetic shielding member 400 is located within the space enclosed by the inner wall of the liner assembly 500, and is disposed outside the accommodation space 110, the magnetic shielding member 400 can be specially designed in the following way.

The recess 401 provided at the lower surface of the end of the magnetic shielding member 400 adjacent to the carrier 200 prevents the magnetic material from depositing at that end, and prevents the magnetic material from adhering at the junction of the magnetic shielding member 400 and the liner assembly 500. This is because once the magnetic material adheres to a certain thickness, the magnetic material is easily peeled off, generating particles that contaminate the wafer.

Consistent with the present disclosure, a gap 402 may be provided between the end of the magnetic shielding member 400 away from the carrier 200 and the liner assembly in a direction parallel to the carrying surface of the carrier 200. The gap 402 prevents adhesion between the end of the magnetic shielding member 400 away from the carrier 200 and the liner assembly.

The present disclosure also includes a liner assembly 500 covering the inner wall of the chamber body 100; the magnetic shielding member 400 is located within the space enclosed by the inner wall of the liner assembly 500; the surface roughness Ra of the upper surface of the magnetic shielding member is in the range of 20 μm to 30 μm. The magnetic shielding member 400 is disposed outside the accommodating space 110, and magnetic material sputtered from the target 810 may fall onto the magnetic shielding member 400. Therefore, embodiments of the present disclosure can improve the surface roughness Ra of the upper surface of the magnetic shielding member 400. For example, the surface roughness Ra of the upper surface of the magnetic shielding member can be set to a range of 20 μm to 30 μm, thereby improving the adhesion between the deposited magnetic material and the upper surface of the magnetic shielding member 400, preventing peeling and wafer contamination. Methods for increasing the surface roughness Ra of the upper surface of the magnetic shielding member 400 include, but are not limited to, providing a textured structure on the upper surface of the magnetic shielding member 400 or lamination.

The present disclosure also provides semiconductor process equipment, including the above-mentioned semiconductor process chamber. Since the semiconductor process equipment includes the above-mentioned semiconductor process chamber, the semiconductor process equipment has all the beneficial effects of the above-mentioned semiconductor process chamber, which will not be repeated here.

Consistent with the present disclosure, a target 810 and a motor 820 for driving the magnetron assembly 800 to rotate are provided above the semiconductor process chamber.

Consistent with the present disclosure, a lifting drive mechanism (not shown in the figure) can also be provided, and the lifting drive mechanism is drivingly connected to the magnetron assembly 800. This lifting drive mechanism is configured to drive the magnetron assembly 800 to move up and down, thereby adjusting the distance between the magnetic field of the magnetron assembly 800 and the bias magnetic field of the bias magnetic field assembly 310. For example, increasing the distance between the two magnetic fields can reduce the adverse effects caused by the magnetic field coupling superposition of the two magnetic fields.

Consistent with the present disclosure, a cover is provided above the semiconductor process chamber for containing deionized water 830.

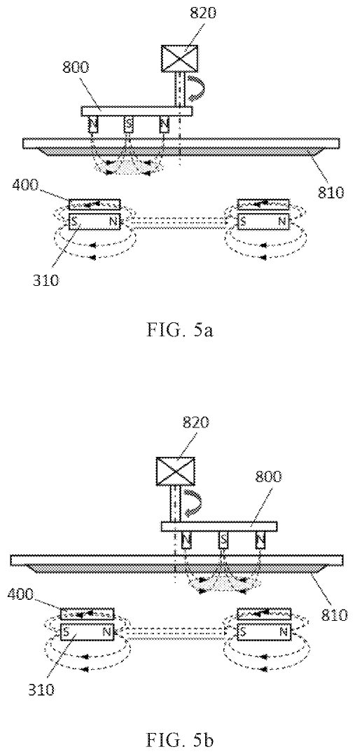

Consistent with the present disclosure, during the sputtering process, as shown in FIGS. 2a-2b, 3a-3b, and 4a-4b, the magnetron assembly 800 rotates above the target 810 under the drive of the motor 820, and the target 810 is cooled by deionized water 830 in the area where the magnetron assembly 800 is located. Due to the magnetic shielding member 400 is capable of magnetic guiding, as shown in FIGS. 2a-2b, 3a-3b, 4a-4b, and 5a-5b, the magnetic shielding member 400 can guide the bias magnetic field above the bias magnetic field assembly 310 from the N pole back to the S pole, thereby reducing the range of the magnetic field above the bias magnetic field assembly 310. In this way, the magnetic field on the surface of the wafer 900 in the horizontal direction will not be affected, and the magnetic field coupling superposition of the bias magnetic field above the bias magnetic field assembly 310 and the magnetic field of the magnetron assembly 800 on the surface of the target 810 can also be weakened, reducing or even avoiding the influence of the rotation of the magnetron assembly 800 on the plasma density on the surface of the target 810, and reducing or even avoiding abnormal fluctuations in the voltage applied to the target during the process, as shown in FIG. 6, where the voltage applied to the target tends to be stable. In addition, the corrosion depth on the surface of the target 810 is essentially uniform, as shown in FIG. 7, which can improve the utilization rate of the target and reduce costs. At the same time, this can also improve the problem of poor uniformity of the magnetic thin film 910 deposited on the surface of the wafer 900, as shown in FIG. 8, resulting in a magnetic thin film 910 with better uniformity on the surface of the wafer 900.

In the present disclosure, the terms associated with “upper,” “lower,” “front,” “horizontal,” etc., indicating orientation or positional relationships are based on the orientation or positional relationships shown in the drawings, and are merely for the convenience of describing the present disclosure and simplifying the description, and are not intended to indicate or imply that the device or element referred to must have a specific orientation, or be constructed and operated in a specific orientation, and therefore should not be understood as a limitation on the present disclosure.

In the present disclosure, unless otherwise explicitly specified and defined, the term “connect” should be understood broadly, for example, it can be a fixed connection, a detachable connection, or an integral connection; it can be a mechanical connection or an electrical connection; it can be directly connected or indirectly connected through an intermediate medium, or it can be a connection within two components. For those skilled in the art, the specific meaning of the above terms in the present disclosure can be understood according to actual needs.

The above embodiments are merely used to illustrate the technical solutions of the present disclosure, and not to limit them. Although the present disclosure has been described in detail with reference to the above embodiments, those skilled in the art should understand that they can still modify the technical solutions described in the foregoing embodiments, or make equivalent substitutions for some or all of the technical features; and these modifications or substitutions do not cause the essence of the corresponding technical solutions to deviate from the scope of the technical solutions of the embodiments of the present disclosure.

What is claimed is:

1. A semiconductor process chamber comprising:
a chamber body;
a carrier configured to carry a wafer;
a magnetron assembly disposed above the carrier;
a bias magnetic field assembly, disposed within the chamber body and surrounding the carrier; and
a magnetic shielding member disposed above the bias magnetic field assembly, configured to guide the magnetic field of the bias magnetic field assembly to reduce magnetic field coupling of the bias magnetic field assembly and the magnetron assembly.

2. The semiconductor process chamber according to claim 1, wherein a downward projection area of the magnetic shielding member covers the bias magnetic field assembly.

3. The semiconductor process chamber according to claim 1, wherein the magnetic shielding member is mainly made of magnetic material.

4. The semiconductor process chamber according to claim 1, further comprising:
a fixation assembly fixed within a space enclosed by an inner wall of the chamber body, the bias magnetic field assembly being fixed to the fixation assembly.

5. The semiconductor process chamber according to claim 4, wherein the fixation assembly includes an upper fixation plate and a lower fixation plate fixed together, the lower fixation plate being fixed within a space enclosed by the inner wall of the chamber body, the bias magnetic field assembly being fixed between the upper fixation plate and the lower fixation plate, and the magnetic shielding member being located above the upper fixation plate;
or, the fixation assembly includes a lower fixation plate fixed within a space enclosed by the inner wall of the chamber body, the bias magnetic field assembly being fixed to an upper surface of the lower fixation plate, and the magnetic shielding member being located above the bias magnetic field assembly;
or, the fixation assembly includes an upper fixation plate fixed within a space enclosed by the inner wall of the chamber body, the bias magnetic field assembly being disposed between the upper fixation plate and the chamber body, and the magnetic shielding member being located above the upper fixation plate.

6. The semiconductor process chamber according to claim 1, further comprising:
a liner assembly covering an inner wall of the chamber body, an accommodation space being provided between an outer wall of the liner assembly and the inner wall of the chamber body; wherein:
the bias magnetic field assembly is fixed within the accommodation space, and the magnetic shielding member is located within the accommodation space or within a space enclosed by an inner wall of the liner assembly; or
both the bias magnetic field assembly and the magnetic shielding member are fixed within the space enclosed by the inner wall of the liner assembly.

7. The semiconductor process chamber according to claim 6, wherein:
the inner wall of the liner assembly forms a stepped space, and a radial dimension of the stepped space decreases sequentially from top to bottom; and
a lower end of the liner assembly extends into a gap between a periphery of the carrier and the chamber body.

8. The semiconductor process chamber according to claim 7, further comprising:
a shielding ring having an annular body, a lower end of the annular body having a first protrusion and a second protrusion extending downwards at intervals, the first protrusion and the second protrusion being arranged sequentially inward along a radial direction; wherein:
a radial dimension of an inner ring of the annular body is smaller than a radial dimension of an outer edge of an upper surface of the carrier, and the inner ring of the annular body is located above the carrier; and
the lower end of the liner assembly includes an upward-facing groove, the first protrusion is inserted into the groove, and the second protrusion is inserted into a gap between an outer wall of the groove and an outer peripheral wall of the carrier.

9. The semiconductor process chamber according to claim 8, wherein:
the lower end of the annular body further includes a third protrusion extending downwards, the first protrusion, the second protrusion, and the third protrusion being arranged sequentially inward along the radial direction, an axial dimension of the third protrusion being smaller than an axial dimension of the second protrusion; and
a part of the third protrusion closer to the carrier includes an inclined surface, the inclined surface slopes radially outward from top to bottom, and the inclined surface is configured to define a relative position of the carrier and the annular body.

10. The semiconductor process chamber according to claim 8, further comprising a heat insulation ring disposed above the shielding ring.

11. The semiconductor process chamber according to claim 1, wherein the semiconductor process chamber includes a plurality of bias magnetic field assemblies, an internal magnetic field direction of the plurality of bias magnetic field assemblies being parallel to a carrying surface of the carrier, and the plurality of bias magnetic field assemblies being distributed in any of the following ways:
in any two adjacent bias magnetic field assemblies of the plurality of bias magnetic field assemblies along a clockwise direction around a circumference of the carrier, the internal magnetic field direction of a following bias magnetic field assembly is rotated clockwise by a predetermined angle relative to the internal magnetic field direction of a preceding bias magnetic field assembly;
in any two adjacent bias magnetic field assemblies of the plurality of bias magnetic field assemblies along a clockwise direction around a circumference of the carrier, the internal magnetic field direction of a following bias magnetic field assembly is rotated counterclockwise by a predetermined angle relative to the internal magnetic field direction of a preceding bias magnetic field assembly;
in any two adjacent bias magnetic field assemblies of the plurality of bias magnetic field assemblies along a counterclockwise direction around a circumference of the carrier, the internal magnetic field direction of a following bias magnetic field assembly is rotated clockwise by a predetermined angle relative to the internal magnetic field direction of a preceding bias magnetic field assembly; or
in any two adjacent bias magnetic field assemblies of the plurality of bias magnetic field assemblies along a counterclockwise direction around a circumference of the carrier, the internal magnetic field direction of a following bias magnetic field assembly is rotated counterclockwise by a predetermined angle relative to the internal magnetic field direction of a preceding bias magnetic field assembly.

12. The semiconductor process chamber according to claim 11, wherein angles of the internal magnetic field directions of any adjacent bias magnetic field assemblies are same or different.

13. The semiconductor process chamber according to claim 11, wherein the angles of the internal magnetic field directions of any adjacent bias magnetic field assemblies range from 5°to 20°.

14. The semiconductor process chamber according to claim 11, further comprising:
a first mounting part; wherein:
the bias magnetic field assembly is fixedly mounted at the chamber body via the first mounting part, the first mounting part is provided with a scale mark, and the chamber body is provided with an installation position mark; and
in any two adjacent bias magnetic field assemblies of the plurality of bias magnetic field assemblies, the scale mark where the first mounting part of the preceding bias magnetic field assembly is aligned with the installation position mark is a first scale mark, and the scale mark where the first mounting part of the following bias magnetic field assembly is aligned with the installation position mark is a second scale mark, an absolute value of a difference between the first scale mark and the second scale mark being a predetermined angle by which the internal magnetic field direction of the following bias magnetic field assembly rotates relative to the internal magnetic field direction of the preceding bias magnetic field assembly.

15. The semiconductor process chamber according to claim 14, further comprising a second mounting part, wherein the bias magnetic field assembly is located between the second mounting part and the first mounting part, and the second mounting part is fixedly connected to the first mounting part by fasteners.

16. The semiconductor process chamber according to claim 15, wherein the second mounting part is annular, and each of the plurality of bias magnetic field assemblies shares the second mounting part; or
the bias magnetic field assembly and the second mounting part are arranged in a one-to-one correspondence.

17. The semiconductor process chamber according to claim 15, wherein the second mounting part is configured to be reused as the magnetic shielding member.

18. The semiconductor process chamber according to claim 1, further comprising a liner assembly covering an inner wall of the chamber body; wherein:
the magnetic shielding member is located within a space enclosed by an inner wall of the liner assembly;
a recess is provided at a lower surface of the magnetic shielding member near the carrier; and/or
in a direction parallel to the carrying surface of the carrier, a gap exists between an end of the magnetic shielding member away from the carrier and the liner assembly.

19. The semiconductor process chamber according to claim 1, further comprising a liner assembly covering the inner wall of the chamber body; wherein:
the magnetic shielding member is located within a space enclosed by an inner wall of the liner assembly; and
a surface roughness Ra of an upper surface of the magnetic shielding member is in a range of 20 μm to 30 μm.

20. Semiconductor process equipment comprising:
a semiconductor process chamber, wherein the semiconductor process chamber includes:
a chamber body;
a carrier configured to carry a wafer;
a magnetron assembly disposed above the carrier;
a bias magnetic field assembly, disposed within the chamber body and surrounding the carrier; and
a magnetic shielding member disposed above the bias magnetic field assembly, configured to guide the magnetic field of the bias magnetic field assembly to reduce magnetic field coupling of the bias magnetic field assembly and the magnetron assembly.
